(19) United States
(12) Patent Application Publication
(10) Pub. No.: US 2026/0076147 A1
(43) Pub. Date: Mar. 12, 2026

(54) SUBSTRATE PROCESSING APPARATUS

(71) Applicant: SEMES CO., LTD., Cheonan-si (KR)

(72) Inventors: Sang Min LEE, Seoul (KR); Seung Hoon OH, Cheonan-si (KR); Yong Hyun CHOI, Cheonan-si (KR); Yong Hee LEE, Cheonan-si (KR); Young Chun CHO, Suwon-si (KR); Yong Joon IM, Yongin-si (KR); Young Hun LEE, Cheonan-si (KR); Tae Jong CHOI, Asan-si (KR); Gil Heyun CHOI, Seoul (KR)

(73) Assignee: SEMES CO., LTD., Cheonan-si (KR)

(21) Appl. No.: 19/323,138

(22) Filed: Sep. 9, 2025

(30) Foreign Application Priority Data
Sep. 9, 2024 (KR) 10-2024-0122230

(51) Int. Cl. H01L 21/687; H01L 21/67

(52) U.S. Cl. CPC H10P 72/7614; H10P 72/0408

(57) ABSTRACT

Provided is an apparatus for processing a substrate, the apparatus including: a housing having a treatment space for processing a substrate inside; and substrate supporter for supporting the substrate in the treatment space, and the substrate supporter includes a first support pin and a second support pin, a height of an upper end of the first support pin is provided to be higher than a height of an upper end of the second support pin, so that when the substrate is placed on the substrate supporter, the substrate is inclined downward from a center to an edge of the substrate. Accordingly, regardless of the manufacturing tolerance, the shape of the substrate supported on the substrate supporter may be constant, and pattern lining phenomenon may be prevented from occurring in the edge region of the substrate.

### CROSS-REFERENCE TO RELATED APPLICATION

This application claims priority to and the benefit of Korean Patent Application No. 10-2024-0122230 filed in the Korean Intellectual Property Office on Sep. 9, 2024, the entire contents of which are incorporated herein by reference.

### TECHNICAL FIELD

The present invention relates to an apparatus for processing a substrate, and more particularly, to an apparatus for processing a substrate by supplying a supercritical fluid to the substrate.

### BACKGROUND ART

In order to manufacture a semiconductor device, a desired pattern is formed on a substrate through various processes, such as photography, etching, ashing, ion implantation, and thin film deposition. Various treatment solutions are used in each process, and contaminants and particles are generated during the process. To solve this problem, a cleaning process for cleaning contaminants and particles is essentially performed before and after each process.

In general, in the cleaning process, the substrate is processed with a chemical and a rinse solution and then dried. The drying treatment step is a process for drying the rinse solution remaining on the substrate, and the substrate is dried with an organic solvent, such as isopropyl alcohol (IPA). However, as the Critical Dimension (CD) between the patterns formed on the substrate becomes finer, the organic solvent remains in the space between the patterns, and the supercritical treatment process proceeds to remove the organic solvent.

The supercritical treatment process is a process of replacing a liquid remaining on a substrate with a supercritical fluid and drying the substrate, and minimizing a region supporting the substrate. FIG. 1 is a top plan view schematically illustrating a substrate supported in a general supercritical treatment apparatus. Referring to FIG. 1, opposite ends of a substrate W are supported by pins 9100. Accordingly, the load of the organic solvent remaining on the substrate W is concentrated toward the central region of the substrate, and a sagging phenomenon occurs in the central region of the substrate W. Accordingly, the organic solvent remaining on the substrate W is moved from the edge region of the substrate W to the central region, and a pattern lining phenomenon occurs in the edge region.

### SUMMARY OF THE INVENTION

The present invention has been made in an effort to provide a substrate processing apparatus capable of improving processing efficiency of a substrate.

The present invention has also been made in an effort to provide a substrate processing apparatus for preventing the occurrence of a pattern lining phenomenon in an edge region of a substrate.

The present invention has also been made in an effort to provide a substrate processing apparatus for preventing a substrate from being bent downward when a substrate is dried with a supercritical fluid.

The present invention has also been made in an effort to provide a substrate processing apparatus having a constant substrate shape when a substrate is supported regardless of manufacturing tolerances.

Effects of the present disclosure are not limited to those described above and effects not stated above will be clearly understood to those skilled in the art from the specification and the accompanying drawings.

An exemplary embodiment of the present disclosure, an apparatus for processing a substrate, the apparatus comprising: a first body; a second body combined with the first body to provide a treatment space for processing the substrate therein, and disposed below the first body; a fluid supply unit for supplying a treatment fluid to the treatment space; a lifting unit for raising and lowering the first body or the second body so that a relative position of the first body and the second body changes between an open position where the treatment space is open to the outside and a closed position where the treatment space is closed off from the outside; a substrate loader which is installed in the first body and in which a substrate loaded or unloaded by an external transfer robot at the open position is placed; and a substrate supporter installed on the second body and supporting the substrate at the closed position, wherein the substrate supporter includes: a support plate; a first support pin and a second support pin which are installed on the support plate to protrude upward from an upper surface of the support plate, and on which the substrate is placed, and a height of an upper end of the first support pin may be higher than a height of an upper end of the second support pin.

According to the exemplary embodiment of the present invention, wherein when viewed from above, the second support pin may be located farther from a center of the substrate than the first support pin while the substrate is supported by the substrate supporter.

According to the exemplary embodiment of the present invention, wherein a plurality of second support pins is provided, and the plurality of second support pins may be arranged to surround the first support pin.

According to the exemplary embodiment of the present invention, wherein the plurality of second support pins may has the same height at upper ends thereof.

According to the exemplary embodiment of the present invention, wherein the first support pin may be provided to support the center of the substrate.

According to the exemplary embodiment of the present invention, wherein a plurality of second support pins is provided, the plurality of second support pins is disposed to surround the first support pin, and a distance between each of the plurality of second support pins and the first support pin may be provided to be the same as each other.

According to the exemplary embodiment of the present invention, wherein intervals between the adjacent second support pins may be provided to be the same as each other.

According to the exemplary embodiment of the present invention, wherein a lower supply port for supplying a treatment fluid to the treatment space is formed on a bottom surface of the second body, the substrate supporter further includes legs supporting the support plate so that the support plate is located at a height spaced apart from the bottom surface of the second body, and when viewed from above, the lower supply port may be formed at a position overlapping the support plate.

According to the exemplary embodiment of the present invention, wherein the first support pin may be installed on the support plate so that a height of the first support pin is adjustable.

According to the exemplary embodiment of the present invention, wherein a first groove formed with a thread is formed in the support plate, and the first support pin may be screw-coupled to the first groove.

According to the exemplary embodiment of the present invention, wherein the substrate loader includes: a plurality of fixed rods fixedly coupled to the first body; a support rod extending from the fixed rod toward an inside thereof and connecting the adjacent fixed rods among the plurality of fixed rods; and a support protrusion formed on an upper surface of the support rod so as to protrude upward from the upper surface of the support rod, and when viewed from above, the support protrusion may be located outside the second support pin.

According to the exemplary embodiment of the present invention, wherein at the open position, an upper end of the support protrusion is higher than an upper end of each of the first support pin and the second support pin, and at the closed position, the upper end of each of the first support pin and the second support pin may be located higher than the support protrusion.

According to the exemplary embodiment of the present invention, wherein the treatment fluid may be a supercritical fluid.

An exemplary embodiment of the present disclosure, an apparatus for processing a substrate, the apparatus comprising: a housing having a treatment space for processing a substrate inside; and a substrate supporter for supporting the substrate in the treatment space, wherein the substrate supporter may be provided to support the substrate to be inclined downward from a center to an edge of the substrate when the substrate is placed on the substrate supporter.

According to the exemplary embodiment of the present invention, wherein the substrate supporter includes a first support pin and a second support pin, an upper end of the first support pin is provided higher than an upper end of the second support pin, and when viewed from above, the second support pin may be located farther from a center of the substrate than the first support pin while the substrate is supported by the substrate supporter.

According to the exemplary embodiment of the present invention, wherein the first support pin supports the center of the substrate, a plurality of second support pins is provided, and the plurality of second support pins may be arranged to surround the first support pin.

According to the exemplary embodiment of the present invention, wherein a distance between each of the plurality of second support pins and the first support pin is the same, and intervals between the adjacent second support pins may be provided to be the same as each other.

According to the exemplary embodiment of the present invention, wherein the plurality of second support pins may has the same height at upper ends thereof.

An exemplary embodiment of the present disclosure, an apparatus for processing a substrate, the apparatus comprising: a first body; a second body combined with the first body to provide a treatment space for processing the substrate therein, and disposed below the first body; a fluid supply unit for supplying a supercritical fluid to the treatment space; a lifting unit for raising and lowering the first body or the second body so that a relative position of the first body and the second body changes between an open position where the treatment space is open to the outside and a closed position where the treatment space is closed off from the outside; a substrate loader which is installed in the first body and in which a substrate loaded or unloaded by an external transfer robot at the open position is placed; and a substrate supporter installed on the second body and supporting the substrate at the closed position, wherein the substrate supporter includes: a support plate; a first support pin and a plurality of second support pins which are installed on the support plate to protrude upward from an upper surface of the support plate, and on which the substrate is placed, the plurality of second support pins having the same height, and an upper end of the first support pin is provided higher than upper ends of the plurality of second support pins, and the first support pin supports a center of the substrate, the plurality of second support pins is arranged to surround the first support pin, and a distance between each of the plurality of second support pins and the first support pin is the same, and intervals between the adjacent second support pins may be provided to be same as each other.

According to the exemplary embodiment of the present invention, wherein the substrate loader includes: a plurality of fixed rods fixedly coupled to the first body; a support rod extending from the fixed rod toward an inside thereof and connecting the adjacent fixed rods among the plurality of fixed rods; and a support protrusion formed on an upper surface of the support rod so as to protrude upward from the upper surface of the support rod, and when viewed from above, the support protrusion is located outside the second support pin, at the open position, an upper end of the support protrusion is located higher than upper ends of the first support pin and each of the second support pin, and at the closed position, upper ends of the first support pin and each of the second support pin are located higher than the support protrusion.

According to the exemplary embodiment of the present invention, it is possible to improve substrate processing efficiency.

According to the exemplary embodiment of the present invention, it is possible to prevent a pattern lining phenomenon in an edge region of a substrate.

According to the exemplary embodiment of the present invention, when a substrate is dried with a supercritical fluid, it is possible to prevent the substrate from being bent downward.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram schematically illustrating a state in which a substrate is supported in a general supercritical chamber.

FIG. 2 is a top plan view schematically illustrating a substrate processing apparatus according to an exemplary embodiment of the present invention.

FIG. 3 is a diagram schematically illustrating a liquid treating chamber of the substrate processing apparatus of FIG. 2 according to an exemplary embodiment.

FIG. 4 is a diagram schematically illustrating a drying chamber of the substrate processing apparatus of FIG. 2 according to an exemplary embodiment.

FIG. 5 is a diagram schematically illustrating a substrate loader of FIG. 4 according to an exemplary embodiment.

FIGS. 6 to 7 are diagrams schematically illustrating a substrate supporter of FIG. 4 according to an exemplary embodiment.

FIG. 8 is a diagram schematically illustrating a state in which the substrate loader loads a substrate in an open position.

FIG. 9 is a diagram schematically illustrating a state in which the substrate supporter supports a substrate in a closed position.

FIG. 10 is a diagram schematically illustrating another example of the substrate supporter of FIG. 7.

FIG. 11 is a diagram schematically illustrating another example of the substrate supporter of FIG. 9.

FIGS. 12 to 13 are diagrams schematically illustrating another example of the drying chamber of FIG. 4.

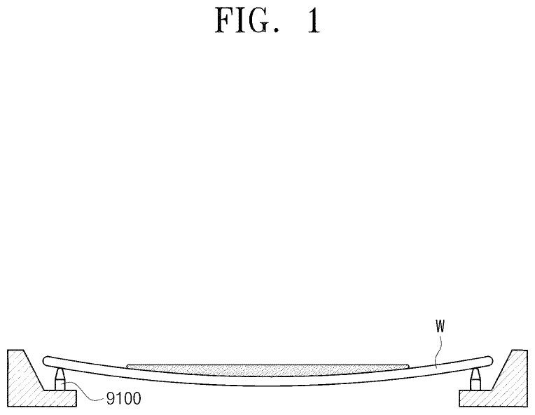

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

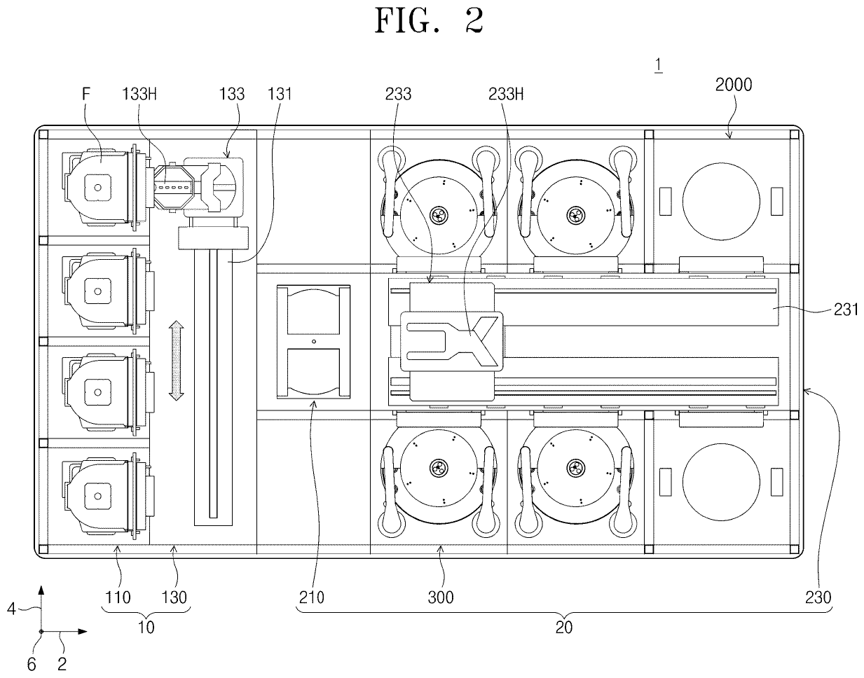

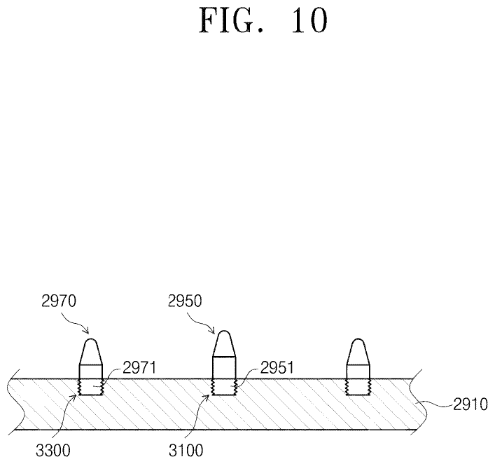

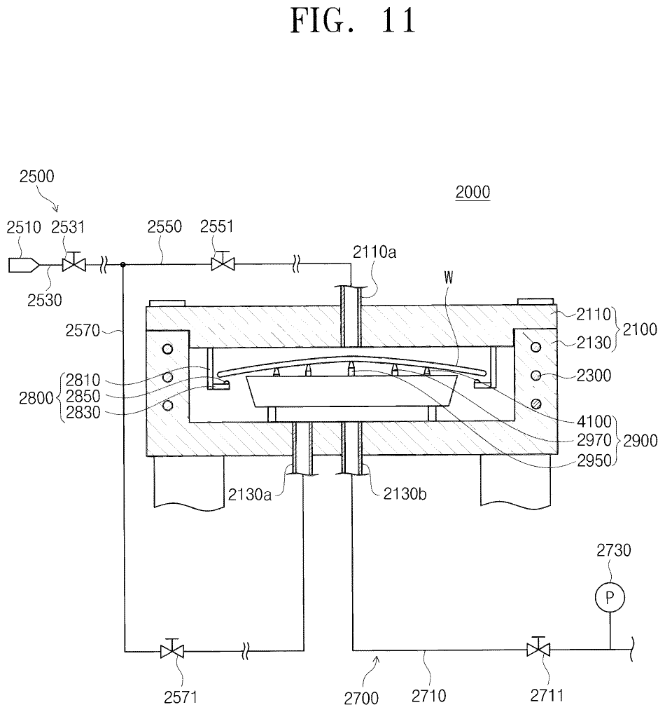

Hereinafter, an exemplary embodiment of the present invention will be described with reference to FIGS. 2 to 13.

FIG. 2 is a top plan view schematically illustrating a substrate processing apparatus according to an exemplary embodiment of the present invention. A substrate processing apparatus 1 includes an index module 10 and a treating module 20. According to the exemplary embodiment, the index module 10 and the treating module 20 are disposed along one direction. Hereinafter, the direction in which the index module 10 and the treating module 20 are disposed is referred to as a first direction 2, and when viewed from above, a direction perpendicular to the first direction 2 is referred to as a second direction 4, and a direction perpendicular to both the first direction 2 and the second direction 4 is referred to as a third direction 6.

The index module 10 transfers a substrate W from a container F in which the substrate W is accommodated to the treating module 20 treating the substrate W. The index module 10 accommodates the substrate W completely processed in the treating module 20 into the container F. A longitudinal direction of the index module 10 is provided in the second direction 4. The index module 10 includes a load port 110 and an index frame 130.

The container F in which the substrate W is accommodated is seated on the load port 110. Based on the index frame 130, the load port 110 is located at a side opposite to the treating module 20. A plurality of load ports 110 may be provided. The plurality of load ports 110 may be arranged in a line along the second direction 4. The number of load ports 110 may increase or decrease according to the process efficiency and footprint conditions of the treating module 20.

A plurality of slots (not illustrated) for accommodating the substrates W in a state of being horizontally arranged with respect to the ground is formed in the carrier F. As the container F, an airtight container, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index rail 131 and an index robot 133 are provided in the index frame 130. The index rail 131 is provided in the index frame 130 along the second direction 4 in its longitudinal direction. The index robot 133 may transfer the substrate W. The index robot 133 may transfer the substrate W between the index module 10 and a buffer unit 210 to be described later.

The index robot 133 may be provided on the index rail 131 to be movable along the second direction 4. The index robot 133 includes a hand 133H. The substrate W may be placed on the hand 133H. The hand 133H is provided to be able to move forward and backward in the first direction 2. Also, the hand 133H may be provided to rotate around the third direction 6 and be movable along the third direction 6. A plurality of hands 133H may be provided. A plurality of hands 133H may be provided to be spaced apart from each other in the vertical direction. A plurality of hands 133H may move forward, backward, and rotate independently of each other.

The treating module 20 includes a buffer unit 210, a transfer chamber 230, a liquid treating chamber 300, and a drying chamber 2000. The buffer unit 210 provides a space in which the substrate W loaded into the treating module 20 and the substrate W unloaded from the treating module 20 stay temporarily. The transfer chamber 230 provides a space for transferring the substrate W between the buffer unit 210 and the liquid treating chamber 300, between the liquid treating chamber 300 and the drying chamber 2000, and between the drying chamber 2000 and the buffer unit 210. The liquid treating chamber 300 performs a liquid treating process of liquid treating the substrate W by supplying a liquid onto the substrate W. For example, the liquid treatment process may be a cleaning process for cleaning the substrate W with a cleaning solution. The drying chamber 2000 performs a process for drying the liquid remaining on the substrate W which has been liquid-treated.

The buffer unit 210 may be disposed between the index frame 130 and the transfer chamber 230. The buffer unit 210 may be located at one end of the transfer chamber 230. A slot (not illustrated) in which the substrate W is placed is provided in the buffer unit 210. A plurality of slots (not illustrated) is provided to be spaced apart from each other along the third direction 6. A front face and a rear face of the buffer unit 210 are opened. The front face is a face facing the index module 10, and the rear face is a face facing the transfer frame 230. The index robot 133 may approach the buffer unit 210 through the front face, and the transfer robot 233 to be described below may approach the buffer unit 210 through the rear face.

The transfer chamber 230 may be provided so that a longitudinal direction is the first direction 2. The liquid treating chamber 300 and the drying chamber 2000 may be disposed on the side of the transfer chamber 230 along the first direction 2. The liquid treating chamber 300 disposed on one side may be disposed closer to the index module 10 based on the first direction 2 than the drying chamber 2000 disposed on the same side. The transfer chamber 230, the liquid treating chamber 300, or the transfer chamber 230 and the drying chamber 2000 may be disposed along the second direction 4.

According to an example, the liquid treating chamber 300 and the drying chamber 2000 may be disposed on opposite sides of the transfer chamber 230, and the liquid treating chambers 300 and the drying chamber 2000 may be provided in an arrangement of A×C1 and B×C2 (A, B, C1, and C2 are each a natural number equal to or greater than 1) on one side of the transfer chamber 230 along the first direction 2 and the third direction 6. Here, A is the number of liquid treating chambers 300 provided in a line along the first direction 2, C1 is the number of liquid treating chambers 300 provided in a line along the third direction 6, B is the number of drying chambers 2000 provided in a line along the first direction 2, and C2 is the number of drying chambers 2000 provided in a line along the third direction 6. For example, when four or six liquid treating chambers 300 and drying chambers 2000 are provided on one side of the transfer chamber 230, the liquid treating chambers 300 and drying chambers 2000 may be arranged in a 2×2 or 2×3 arrangement, respectively. The number of liquid treating chambers 300 and the number of drying chambers 2000 may increase or decrease. Unlike the above description, the liquid treating chamber 300 and the drying chamber 2000 may be provided only on one side of the transfer chamber 230, and may be provided as a single layer on one side or opposite sides of the transfer chamber 230. In addition, only the liquid treating chambers 300 may be provided on one side of the transfer chamber 230, and only the drying chambers 2000 may be provided on the other side.

The transfer chamber 230 includes a guide rail 231 and a transfer robot 233. The guide rail 231 is provided within the transfer chamber 230 in the first direction 2 in a longitudinal direction thereof. The transfer robot 233 may be provided on the guide rail 231 to be able to move linearly along the first direction 2. The transfer robot 233 transfers the substrate W between the buffer unit 210 and the liquid treating chamber 300, between the liquid treating chamber 300 and the drying chamber 2000, and between the drying chamber 2000 and the buffer unit 210.

The transfer robot 233 includes a hand 233H on which the substrate W is placed. The hand 233H may be provided on the guide rail 231 to be movable along the first direction 2. Accordingly, the hand 233H may be moved forward and backward along the guide rail 231. In addition, the hand 233H may be provided to be rotated around the third direction 6 and be movable along the third direction 6. A plurality of hands 233H may be provided. A plurality of hands 233H may be provided to be spaced apart from each other in the vertical direction. The plurality of hands 233H may move forward, backward, and rotate independently of each other.

The liquid treating chamber 300 performs a liquid treatment process on the substrate W. For example, the liquid treating chamber 300 may be a chamber that performs a cleaning process for removing process by-products or the like attached to the substrate W.

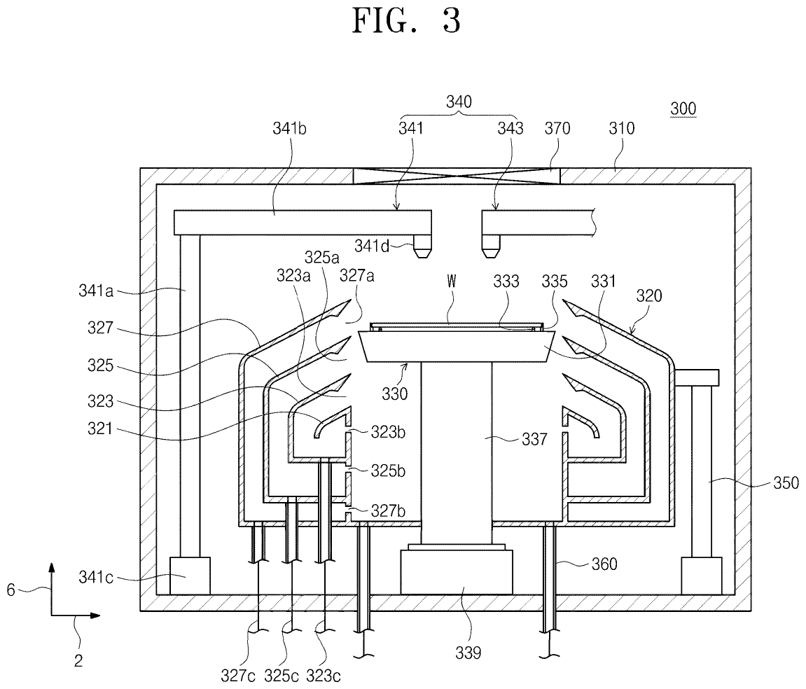

FIG. 3 is a diagram schematically illustrating the liquid treating chamber of the substrate processing apparatus of FIG. 2 according to an exemplary embodiment. The process chamber includes a housing 310, a treatment container 320, a support unit 330, a liquid supply unit 340, a lifting unit 350, an exhaust unit 360, and an airflow supply unit 370.

The housing 310 has an inner space. The housing 310 is provided in a generally rectangular parallelepiped shape. An opening (not illustrated) is formed at one side of the housing 310. The opening (not illustrated) functions as an entrance through which the substrate W is loaded into the inner space or the substrate W is unloaded from the inner space. The treatment container 320, the support unit 330, the liquid supply unit 340, and the airflow supply unit 370 are disposed within the housing 310.

The treatment container 320 has a treatment space with an open top. The treatment container 320 may have a bowl shape. The substrate W is located in a treatment space and supplies a liquid onto the substrate W in the treatment space. The liquid may be provided in a plurality of types, and may be sequentially supplied onto the substrate W.

The treatment container 320 may include a guide wall 321 and a plurality of recovery tanks 323, 325, and 327. Each of the recovery tanks 323, 325, and 327 separates and recovers a different liquid from among liquids used for the treatment of the substrate W. Each of the recovery tanks 323, 325, and 327 has a recovery space for recovering the liquid used for the processing of the substrate. The guide wall 321 and the recovery tanks 323, 325, and 327 are provided in an annular ring shape surrounding the support unit 330. As the liquid treatment process proceeds, the liquid scattered by the rotation of the substrate W is introduced into the recovery space through inlets 323a, 325a, and 327a of the respective recovery tanks.

According to an example, the treatment container 320 has the guide wall 321, a first recovery tank 323, a second recovery tank 325, and a third recovery tank 327. The guide wall 321 is provided in an annular ring shape surrounding the support unit 330, and the first recovery tank 323 is provided in an annular ring shape surrounding the guide wall 321. The second recovery tank 325 is provided with an annular ring shape surrounding the first recovery tank 323, and the third recovery tank 327 is provided with an annular ring shape surrounding the second recovery tank 325. A space between the first recovery tank 323 and the guide wall 321 functions as a first inlet 323a through which a liquid is introduced. A space between the first recovery tank 323 and the second recovery tank 325 functions as a second inlet 325a through which a liquid is introduced. A space between the second recovery tank 325 and the third recovery tank 327 functions as a third inlet 327a through which a liquid is introduced. The second inlet 325a may be located above the first inlet 323a, and the third inlet 327a may be located above the second inlet 325a.

A space between the lower end of the guide wall 321 and the first recovery tank 323 functions as a first outlet 323b through which fume and airflow generated from the liquid are discharged. A space between a lower end of the first recovery tank 323 and the second recovery tank 325 functions as a second outlet 325b through which fume and airflow generated from the liquid are discharged. A space between a lower end of the second recovery tank 325 and the third recovery tank 327 functions as a third outlet 327b through which fume and airflow generated from the liquid are discharged. Fume and airflow discharged from the first outlet 323b, the second outlet 325b, and the third outlet 327b are exhausted through the exhaust unit 360 to be described later.

Recovery lines 323c, 325c, and 327c extending vertically in a direction below the bottom surfaces of the recovery tanks 323, 325, and 327 are connected to the recovery tanks 323, 325, and 327, respectively. The recovery lines 323c, 325c, and 327c discharges a treatment solution introduced through the recovery tanks 323, 325, and 327, respectively. The discharged treatment solution may be reused by an external treatment solution regeneration system (not illustrated).

The support unit 330 supports and rotates the substrate W in the treatment space. The support unit 330 includes a spin chuck 331, a support pin 333, a chuck pin 335, a rotation shaft 337, and a driver 339.

The top surface of the spin chuck 331 is generally provided in a circular shape when viewed from above. The top surface of the spin chuck 331 may be provided to have a larger diameter than the substrate W.

A plurality of support pins 333 is provided. The support pin 333 is disposed on the top surface of the spin chuck 331. The support pin 333 is disposed on the edge of the top surface of the spin chuck 331 to be spaced apart from each other at a predetermined interval. The support pin 333 protrudes upward from the top surface of the spin chuck 331. The support pins 333 are disposed to have an annular ring shape as a whole by a combination thereof. The support pin 333 supports the edge of the back surface of the substrate W so that the substrate W is spaced apart from the top surface of the spin chuck 331 by a predetermined distance.

A plurality of chuck pins 335 is provided. The chuck pin 335 is disposed to be relatively farther from the center of the spin chuck 331 than the support pin 333. The support pin 335 protrudes from the top surface of the spin chuck 331. The chuck pin 335 supports a side portion of the substrate W so as to prevent the substrate W from being separated from the correct position in the lateral direction when the substrate W is rotated. The chuck pin 335 is provided to be able to move linearly between a standby position and a support position along a radial direction of the spin chuck 331. For example, the chuck pin 335 may be linearly moved in the radial direction of the substrate W between the standby position and the support position. The standby position is a position farther from the center of the spin chuck 331 than the support position. When the substrate W is loaded into or unloaded from the support unit 330, the chuck pin 335 is located at the standby position, and the chuck pin 335 is located at the support position when performing a process on the substrate W. In the support position, the chuck pin 335 is in contact with the side portion of the substrate W.

The rotation shaft 337 is coupled to the spin chuck 331. The rotation shaft 337 may be coupled to a lower surface of the spin chuck 331. The rotation shaft 337 may be provided such that a longitudinal direction thereof faces a vertical direction. The rotation shaft 337 is provided to be rotatable by receiving power from the driver 339. The rotation shaft 337 is rotated by the driver 339, thereby rotating the spin chuck 331. The driver 339 may vary the rotation speed of the rotation shaft 337. The driver 339 may be a motor that provides driving force. However, the present invention is not limited thereto, and may be variously modified and provided as a known device that provides driving force.

The liquid supply unit 340 supplies a liquid to the substrate W. The liquid supply unit 340 supplies the liquid to the substrate W supported by the support unit 330. A plurality of liquid supply units 340 is provided, and each supplies a different type of liquid. According to an example, the liquid supply unit 340 may include a first liquid supply member 341 and a second liquid supply member 343.

The first liquid supply member 341 includes a support shaft 341a, a support arm 341b, a driver 341c, and a nozzle 341d. The support shaft 341a is located at one side of the treatment container 320. The support shaft 341a has a rod shape whose longitudinal direction is oriented toward the third direction 6. The support rod 341a is provided to be rotatable by the driver 341c. The support arm 341b is coupled to an upper end of the support shaft 341a. The support arm 341b extends vertically from the support shaft 341a. The nozzle 341d is fixed and coupled to a distal end of the support arm 341b. As the support shaft 341a rotates, the nozzle 341d may swing and move together with the support arm 341b. The nozzle 341d may be swing-moved to the process position and the standby position. When viewed from above, the process position is a position at which the nozzle 341d faces the substrate W supported by the support unit 330, and the standby position is a position at which the nozzle 341d is out of the process position.

The second liquid supply member 343 supplies a second liquid onto the substrate W supported by the support unit 330. Since the second liquid supply member 343 has the same shape as that of the first liquid supply member 341, a detailed description of the second liquid supply member 343 will be omitted below.

The first liquid and the second liquid may be any one of a chemical, a rinse solution, and an organic solvent. For example, the chemical may include diluted sulfuric acid (H₂SO₄), diluted sulfonic acid peroxide (P₂O₅), hydrofluoric acid (HF), and ammonium hydroxide (NH₄OH). For example, the rinse solution may include water or deionized water (DIW). For example, the organic solvent may contain alcohol, such as isopropyl alcohol (IPA).

The lifting unit 350 is disposed in the housing 310. The lifting unit 350 adjusts the relative height between the treatment container 320 and the support unit 330. The lifting unit 350 may linearly move the treatment container 320 in the third direction 6. Unlike the description, the treatment container 320 is fixedly installed, and the lifting unit 350 may move the support unit 330 in the vertical direction.

The exhaust unit 360 exhausts fume and gas generated in the treatment space. The exhaust unit 360 exhausts fume and gas generated when the substrate W is liquid-treated. The exhaust unit 360 may be coupled to the bottom surface of the treatment container 320. For example, the exhaust unit 360 may be disposed in the space between the rotation shaft 337 of the support unit 330 and an inner wall of the treatment container 320. A decompression unit (not illustrated) is provided in the exhaust unit 360. Fume and gas generated when the substrate W is liquid treated are exhausted from the treatment space to the outside of the treatment space by the decompression unit.

The airflow supply unit 370 supplies airflow to the inner space of the housing 310. The airflow supply unit 370 may supply descending airflow to the inner space. The airflow supply unit 370 may be installed in the housing 310. The airflow supply unit 370 may be installed on a ceiling of the housing 310. Gas supplied to the inner space of the housing 310 through the airflow supply unit 370 forms a descending airflow in the inner space. Gas by-products generated by the treatment process in the treatment space are discharged to the outside of the housing 310 through the exhaust pipe 360 by the descending airflow. The airflow supply unit 370 may be provided to a Fan Filter Unit (FFU).

The drying chamber 2000 performs a process for drying the liquid remaining on the substrate W which has been liquid-treated. The drying chamber 2000 may dry the cleaning liquid remaining on the substrate W by supplying the supercritical fluid. For example, the drying chamber 2000 may perform a drying process of removing the organic solvent remaining on the substrate W using carbon dioxide in a supercritical state.

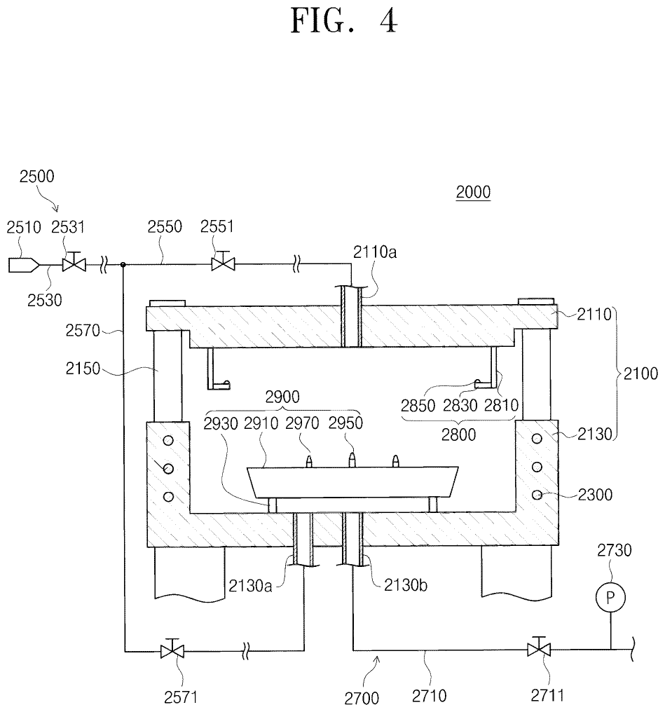

FIG. 4 is a diagram schematically illustrating the drying chamber of the substrate processing apparatus of FIG. 2 according to an exemplary embodiment.

The drying chamber 2000 includes a housing 2100, a heating member 2300, a fluid supply unit 2500, an exhaust unit 2700, a substrate loader 2800, and a substrate supporter 2900.

The housing 2100 has a first body 2110 and a second body 2130. The first body 2110 and the second body 2130 are combined with each other to provide a treatment space therein. The first body 2110 is located above the second body 2130. The first body 2110 and the second body 2130 are made of a material capable of withstanding a high pressure equal to or higher than a critical pressure and a high temperature equal to or higher than a critical temperature of the supercritical fluid.

The lifting unit 2150 adjusts a relative position between the first body 2110 and the second body 2130. The lifting unit 2150 raises and lowers the first body 2110 or the second body 2130 so that a relative position of the first body 2110 and the second body 2130 is changed between an open position and a closed position. For example, a position of the first body 2110 is fixed, and the second body 2130 may be raised and lowered by the lifting unit 2150. The open position is a position where the first body 2110 and the second body 2130 are spaced apart from each other to open he treatment space to the outside, and the closed position is a position where the first body 2110 and the second body 2130 are in close contact with each other to close the treatment space from the outside. The lifting unit 2150 may include a cylinder. Selectively, the lifting unit 2150 may include a motor.

The heating member 2300 heats a treatment fluid supplied to the treatment space. The heating member 2300 increases the temperature inside the treatment space. When the heating member 2300 increases the temperature of the treatment space, the treatment fluid supplied to the treatment space is converted into a supercritical state or the treatment fluid is maintained in a supercritical state.

Also, the heating member 2300 may be buried in the housing 2100. The heating member 2300 may be buried in at least one of the first body 2110 and the second body 2130. For example, the heating member 2300 may be provided in each of the first body 2110 and the second body 2130. The heating member 2300 may be a heater.

The fluid supply unit 2500 supplies a treatment fluid to the treatment space. The fluid supply unit 2500 includes a treatment fluid supply source 2510, a main supply pipe 2530, an upper supply pipe 2550, and a lower supply pipe 2570.

The treatment fluid supply source 2510 stores and supplies the treatment fluid. The treatment fluid supply source 2510 includes a reservoir. The treatment fluid is supplied to the reservoir in a liquid state. The treatment fluid is phase-changed to a supercritical state in the reservoir. The treatment fluid supply source 2510 supplies the treatment fluid to the treatment space through the supply pipes 2530, 2550, and 2570.

The main supply pipe 2530 is connected to the treatment fluid supply source 2510. The main supply pipe 2530 is branched to an upper supply pipe 2550 and a lower supply pipe 2570 to supply the treatment fluid to the treatment space. An opening/closing valve 2531 capable of opening and closing the internal flow path thereof is installed in the main supply pipe 2530. Components, such as a heater, a sensor, and a filter, may be installed in the main supply pipe 2530.

The upper supply pipe 2550 is branched from the main supply pipe 2530 to supply the treatment fluid to the upper end of the treatment space. An upper supply port 2110a is provided in the first body 2110. The upper supply pipe 2550 may be connected to the first body 2110 through the upper supply port 2110a. The upper supply port 2110a may be formed at the center of the first body 2110. An opening/closing valve 2551 capable of opening and closing the internal flow path thereof is installed in the upper supply pipe 2550.

The lower supply pipe 2570 is branched from the main supply pipe 2530 to supply the treatment fluid to a lower end of the treatment space. A lower supply port 2130a is provided in the second body 2130. The lower supply pipe 2570 may be connected to the second body 2130 through the lower supply port 2130a. The lower supply port 2130a may be formed at a point eccentric from the center of the second body 2130. An opening/closing valve 2571 capable of opening and closing the internal flow path thereof is installed in the lower supply pipe 2570.

The exhaust unit 2700 exhausts a treatment fluid remaining in the treatment space to the outside. The exhaust unit 2700 includes an exhaust pipe 2710 and a decompression pump 2730. An exhaust port 2130b is provided in the second body 2130. The exhaust port 2310b may be formed at the center of the second body 2130. The exhaust pipe 2710 may be connected to the second body 2130 through an exhaust port 2130b. An opening/closing valve 2711 capable of opening and closing an internal flow path thereof is installed in the exhaust pipe 2710. The decompression pump 2730 may be installed in the exhaust pipe 2710.

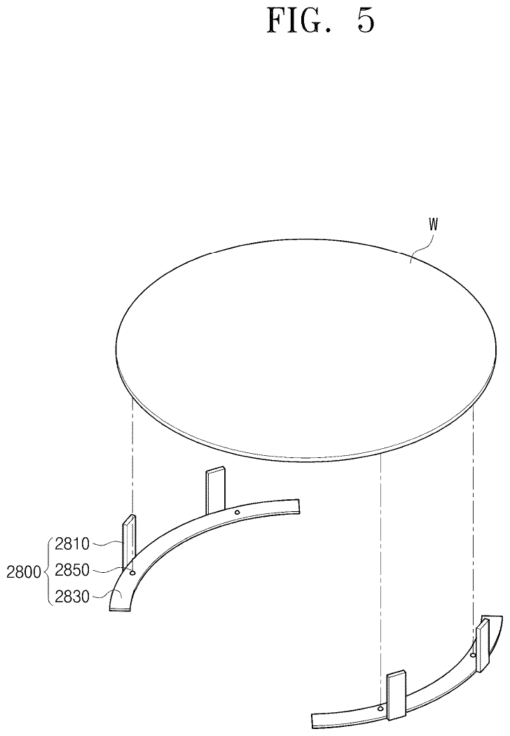

A substrate loader 2800 is installed in the first body 2110. When the first body 2110 and the second body 2130 are in the open position, the substrate W is loaded into or unloaded from the treatment space by the transfer robot 233. The substrate W loaded into the treatment space from the transfer robot 233 is supported by the substrate loader 2800. Also, the substrate W, on which the process has been completed, is unloaded from the treatment space by the transfer robot 233 in a state of being supported by the substrate loader 2800. FIG. 5 is a diagram schematically illustrating the substrate loader of FIG. 4 according to an exemplary embodiment. Referring to FIG. 5, the substrate loader 2800 includes a fixed rod 2810, a support rod 2830, and a support protrusion 2850.

The fixed rod 2810 is provided in a bar shape extending downward from the bottom surface of the first body 2110. A plurality of fixed rods 2810 is provided. According to an example, four fixed rods 2810 may be provided.

The support rod 2830 extends from the fixed rod 2810 toward the inside thereof. The support rod 2830 is provided perpendicular to the fixed rod 2810. The support rod 2830 connects two adjacent fixed rods 2810. The support rod 2830 has an arc shape. A plurality of support rods 2830 is provided. According to an example, two support rods 2830 may be provided.

The support protrusion 2850 protrudes upward from the upper surface of the support rod 2830 and extends. The upper surface of the support protrusion 2850 directly supports an edge region of the bottom surface of the substrate W. The upper surface of the support protrusion 2850 may be provided to be round. A plurality of support protrusions 2850 is provided. According to an example, two support protrusions 2850 may be provided on each support rod 2830.

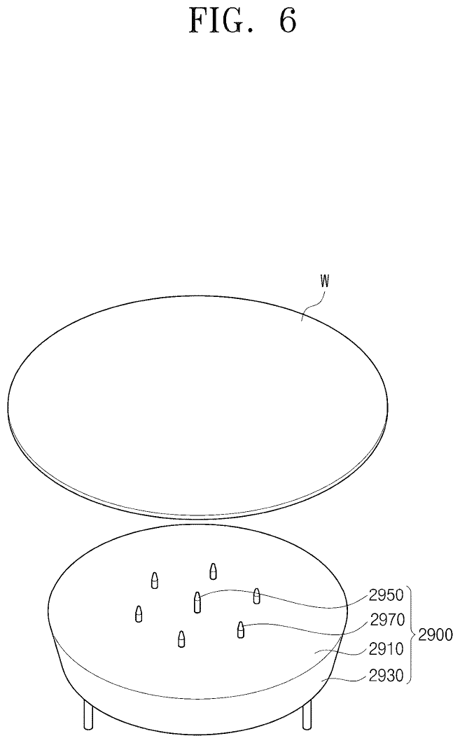

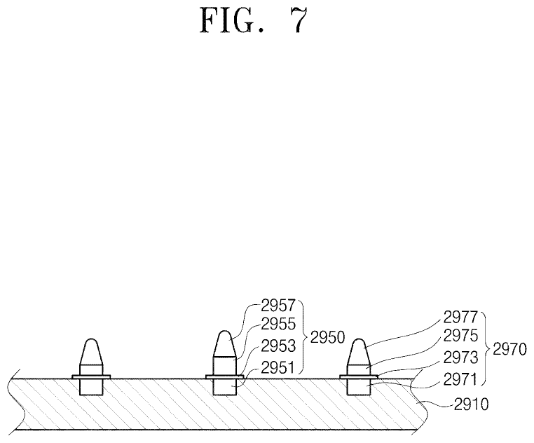

A substrate supporter 2900 is installed in the second body 2130. In the treatment space, the substrate W is processed while being supported by the substrate supporter 2900. When the first body 2110 and the second body 2130 are in the closed position, the substrate W is supported by the substrate supporter 2900. FIGS. 6 to 7 are diagrams schematically illustrating the substrate supporter of FIG. 4 according to an exemplary embodiment. Referring to FIG. 6, the substrate supporter 2900 includes a support plate 2910, a leg 2930, a first support pin 2950, and a second support pin 2970.

The support plate 2910 is disposed in the treatment space. When viewed from above, the lower supply port 2130a and the exhaust port 2130b are formed at positions overlapping the support plate 2910. Accordingly, the treatment fluid flowing through the lower supply port 2130a flows upward by bypassing the support plate 2910. The support plate 2910 may prevent the treatment fluid introduced through the lower supply port 2130a from directly hitting the substrate W and damaging the substrate W.

The leg 2930 supports the support plate 2910. The support plate 2910 is located to be spaced apart from the bottom surface of the second body 2130 by a predetermined distance by the leg 2930. A plurality of legs 2930 is provided. The legs 2930 are arranged along the circumferential direction of the support plate 2910. The legs 2930 are arranged to be spaced apart from each other by a predetermined distance.

The first support pin 2950 and the second support pin 2970 are installed to protrude upward from the upper surface of the support plate 2910. While the substrate W is being processed in the treatment space, the bottom surface of the substrate W is directly supported by the first support pin 2950 and the second support pin 2970. A height of an upper end of the first support pin 2950 is higher than a height of an upper end of the second support pin 2970.

One first support pin 2950 is provided. The first support pin 2950 supports the center of the substrate W.

A plurality of second support pins 2970 is provided. A plurality of second support pins 2970 have the same height at the upper end, respectively. A plurality of second support pins 2970 is arranged to surround the first support pin 2950. A distance between each of the plurality of second support pins 2970 and the first support pin 2950 is provided to be the same as each other. The intervals between adjacent ones of the plurality of second support pins 2970 are provided to be the same as each other. That is, the second support pins 2970 are arranged on a virtual circumference centered on the first support pin 2950. According to an example, six second support pins 2970 are provided.

Referring to FIG. 7, the first support pin 2950 and the second support pin 2970 have insertion parts 2951 and 2971, ring parts 2953 and 2973, body parts 2955 and 2975 and contact parts 2957 and 2977, respectively.

The insertion parts 2951 and 2971 are parts at which the first support pin 2950 and the second support pin 2970 are coupled to the support plate 2910. According to an exemplary embodiment, the first support pin 2950 and the second support pin 2970 may be press-fitted into the support plate 2910 and fixedly installed. Thus, ring parts 2953 and 2973 may be provided around the insertion parts 2951 and 2971 so that the first support pin 2950 and the second support pin 2970 may be press-fitted by a designed distance.

The body parts 2955 and 2975 vertically extend upward from the insertion parts 2951 and 2971. The body parts 2955 and 2975 may have a cylindrical shape. The contact parts 2957 and 2977 are parts that are in direct contact with the substrate W. The contact parts 2957 and 2977 may have a substantially conical shape. The end parts of the contact parts 2957 and 2977 may be rounded.

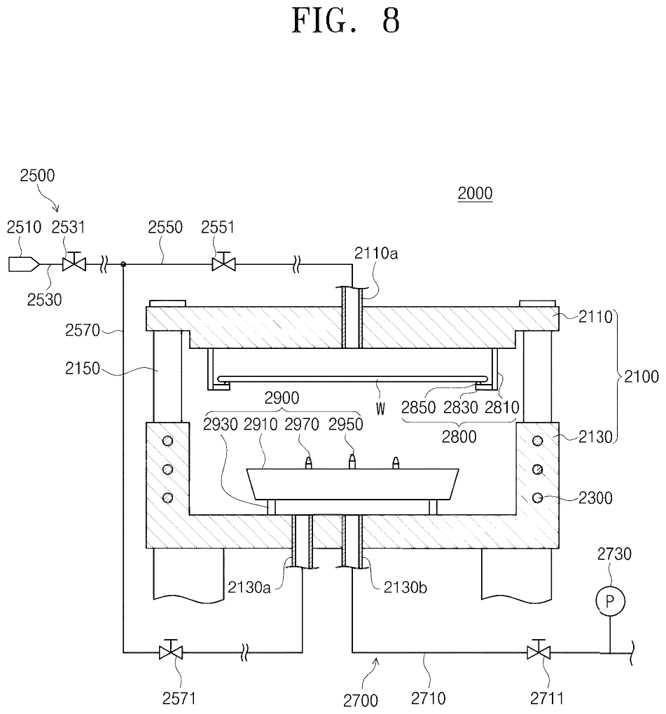

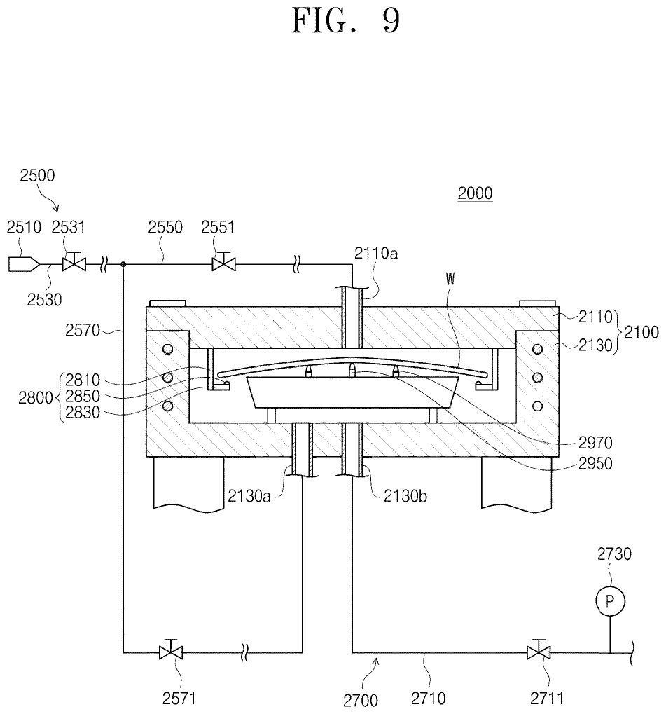

FIG. 8 is a diagram schematically illustrating a state in which the substrate loaders loads the substrate in the open position. FIG. 9 is a diagram schematically illustrating a state in which the substrate support supports the substrate in the closed position.

Referring to FIG. 8, an upper end of the support protrusion 2850 is located higher than upper ends of the first support pin 2950 and the second support pin 2970 in the open position. After liquid treatment, the substrate W is handed over to the substrate loader 2800 by the transfer robot 233. That is, when the first body 2110 and the second body 2130 are located in the open position, the substrate W loaded into the treatment space by the transfer robot 233 is placed on the support protrusion 2850.

Thereafter, as illustrated in FIG. 9, the second body 2130 ascends with respect to the first body 2110 and is located at the closed position. When viewed from above, the support protrusion 2850 is located outside the support plate 2910 and the second support pin 2970, and at the closed position, the upper end of the first support pin 2950 is located higher than the upper ends of the second support pin 2970 and the support protrusion 2850.

Sagging occurs due to the weight of the substrate W and the weight of the liquid film formed on the upper surface of the substrate W, so that the substrate W is formed to be inclined downward from the center thereof to the edge thereof, and the substrate W is supported by the first support pin 2950 and the second support pin 2970. According to an example, even if the sagging phenomenon of the substrate W occurs at the closed position, the substrate W is supported only by the first support pin 2950 and the second support pin 2970.

When the heights of the upper ends of the first support pin 2950 and the second support pin 2970 are designed to be the same, the heights of the upper ends of the first support pin 2950 and the second support pin 2970 are not exactly the same due to the manufacturing tolerance. Accordingly, it is difficult to predict the shape of the substrate W supported by the substrate supporter 2900, and the pattern lining phenomenon still occurs in the edge region of the substrate W. On the other hand, in the present invention, since the upper end of the first support pin 2950 is designed to be higher than the upper end of each of the second support pin 2970 and the support protrusion 2850 in the closed position, even if manufacturing tolerance occurs during the manufacturing process, the upper end of the first support pin 2950 is located higher than the upper end of each of the second support pin 2970 and the support protrusion 2850 in the closed position. Accordingly, regardless of the manufacturing tolerance, the substrate W may always have a shape inclined downward from the center to the edge thereof in the closed position. In addition, since the liquid film remaining in the edge region of the substrate W is not moved to the central region of the substrate W, it is possible to prevent the occurrence of a pattern lining phenomenon in the edge region of the substrate W.

In the above-described exemplary embodiment of FIG. 7, the case where the first support pin and the second support pin are press-fitted into the support plate and installed has been described as an example. However, the present invention is not limited thereto, and the support plate 2910 may be provided with a first groove 3100 in which a thread is formed and a second groove 3300 in which a thread is formed. The insertion part 2951 of the first support pin 2950 may be screw-coupled to the first groove 3100, and the insertion part 2971 of the second support pin 2970 may be screw-coupled to the second groove 3300. Accordingly, the heights of the first support pin 2950 and the second support pin 2970 may be adjusted with respect to the support plate 2910.

In the exemplary embodiment of FIG. 9 described above, the case where the substrate supporter includes the first support pin and the second support pin has been described as an example. However, the present invention is not limited thereto, and a third support pin 4100 may be further provided on the substrate supporter 2900. A plurality of third support pins 4100 may be provided. The third support pin 4100 may be arranged to surround the first support pin 2950. For example, the third support pin 4100 may be arranged on a virtual circumference centered on the first support pin 2950. A height of an upper end of the third support pin 4100 may be lower than a height of an upper end of the second support pin 2970. The third support pin 4100 may be located farther from the center of the substrate W than the second support pin 2970 in a state where the substrate W is supported by the substrate supporter 2900.

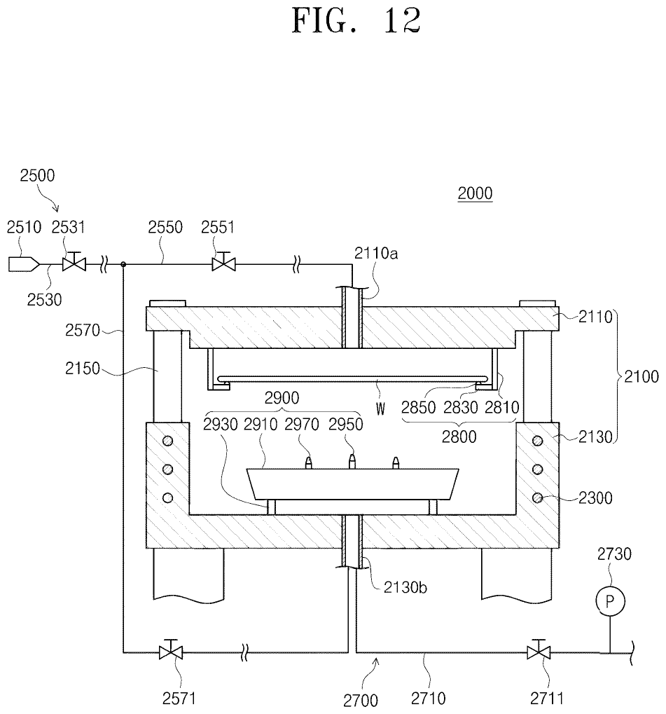

In the above-described exemplary embodiment of FIG. 4, the case where the lower supply port and the exhaust port are respectively formed in the second body has been described as an example. The present invention is not limited thereto, and as illustrated in FIG. 12, one port 5100 may be provided at the center of the second body 2130, and the lower supply pipe 2570 and the exhaust pipe 2710 may share one port.

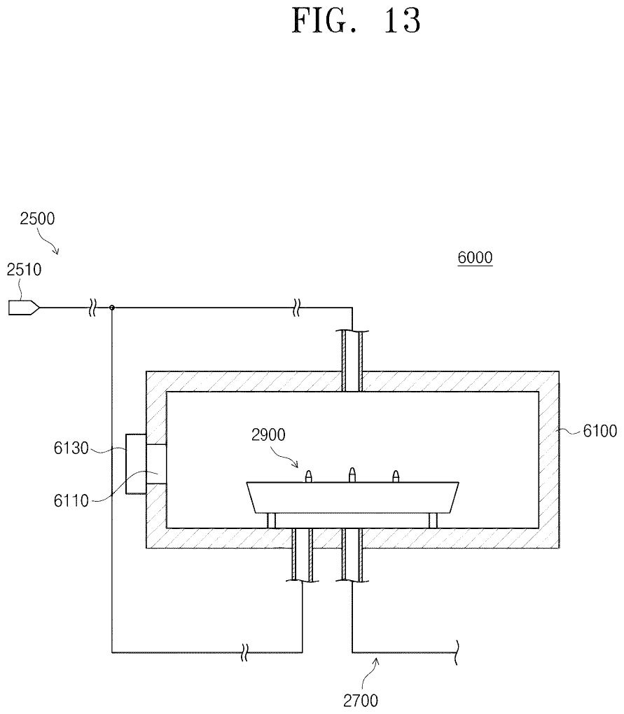

In an exemplary embodiment of FIG. 4 described above, the case where the drying chamber includes the first body and the second body has been described as an example. However, the present invention is not limited thereto, and as illustrated in FIG. 13, the drying chamber 6000 may include a housing 6100 having a treatment space, and a substrate supporter 2900 that supports a substrate in the treatment space. The housing 6100 has an opening 6110 through which a substrate may be loaded and unloaded, and a door 6130 that may open and close the opening 6110 may be installed. When the door 6130 opens the opening 6110, the substrate W may be supported by the substrate supporter 2900 by the transfer robot 233. Thereafter, the door 6130 may close the opening 6110 and supply a treatment fluid to treat the substrate.

In the above exemplary embodiments, the case where the upper ends of the first support pin, the second support pin, and the support protrusion are formed to be round has been described as an example. However, unlike this, the upper ends of each of the first support pin 2950, the second support pin 2970, and the support protrusion 2850 may be provided to be flat.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. An apparatus for processing a substrate, the apparatus comprising:
a first body;
a second body combined with the first body to provide a treatment space for processing the substrate therein, and disposed below the first body;
a fluid supply unit for supplying a treatment fluid to the treatment space;
a lifting unit for raising and lowering the first body or the second body so that a relative position of the first body and the second body changes between an open position where the treatment space is open to the outside and a closed position where the treatment space is closed off from the outside;
a substrate loader which is installed in the first body and in which a substrate loaded or unloaded by an external transfer robot at the open position is placed; and
a substrate supporter installed on the second body and supporting the substrate at the closed position,
wherein the substrate supporter includes:
a support plate;
a first support pin and a second support pin which are installed on the support plate to protrude upward from an upper surface of the support plate, and on which the substrate is placed, and
a height of an upper end of the first support pin is higher than a height of an upper end of the second support pin.

2. The apparatus of claim 1, wherein when viewed from above, the second support pin is located farther from a center of the substrate than the first support pin while the substrate is supported by the substrate supporter.

3. The apparatus of claim 2, wherein a plurality of second support pins is provided, and
the plurality of second support pins is arranged to surround the first support pin.

4. The apparatus of claim 3, wherein the plurality of second support pins has the same height at upper ends thereof.

5. The apparatus of claim 1, wherein the first support pin is provided to support the center of the substrate.

6. The apparatus of claim 5, wherein a plurality of second support pins is provided,
the plurality of second support pins is disposed to surround the first support pin, and
a distance between each of the plurality of second support pins and the first support pin is provided to be the same as each other.

7. The apparatus of claim 6, wherein intervals between the adjacent second support pins are provided to be the same as each other.

8. The apparatus of claim 2, wherein a lower supply port for supplying a treatment fluid to the treatment space is formed on a bottom surface of the second body,
the substrate supporter further includes legs supporting the support plate so that the support plate is located at a height spaced apart from the bottom surface of the second body, and
when viewed from above, the lower supply port is formed at a position overlapping the support plate.

9. The apparatus of claim 1, wherein the first support pin is installed on the support plate so that a height of the first support pin is adjustable.

10. The apparatus of claim 9, wherein a first groove formed with a thread is formed in the support plate, and
the first support pin is screw-coupled to the first groove.

11. The apparatus of claim 1, wherein the substrate loader includes:
a plurality of fixed rods fixedly coupled to the first body;
a support rod extending from the fixed rod toward an inside thereof and connecting the adjacent fixed rods among the plurality of fixed rods; and
a support protrusion formed on an upper surface of the support rod so as to protrude upward from the upper surface of the support rod, and
when viewed from above, the support protrusion is located outside the second support pin.

12. The apparatus of claim 11, wherein at the open position, an upper end of the support protrusion is higher than an upper end of each of the first support pin and the second support pin, and
at the closed position, the upper end of each of the first support pin and the second support pin is located higher than the support protrusion.

13. The apparatus of claim 1, wherein the treatment fluid is a supercritical fluid.

14. An apparatus for processing a substrate, the apparatus comprising:
a housing having a treatment space for processing a substrate inside; and
a substrate supporter for supporting the substrate in the treatment space,
wherein the substrate supporter is provided to support the substrate to be inclined downward from a center to an edge of the substrate when the substrate is placed on the substrate supporter.

15. The apparatus of claim 14, wherein the substrate supporter includes a first support pin and a second support pin,
an upper end of the first support pin is provided higher than an upper end of the second support pin, and
when viewed from above, the second support pin is located farther from a center of the substrate than the first support pin while the substrate is supported by the substrate supporter.

16. The apparatus of claim 15, wherein the first support pin supports the center of the substrate,
a plurality of second support pins is provided, and
the plurality of second support pins is arranged to surround the first support pin.

17. The apparatus of claim 16, wherein a distance between each of the plurality of second support pins and the first support pin is the same, and intervals between the adjacent second support pins are provided to be the same as each other.

18. The apparatus of claim 16, wherein the plurality of second support pins has the same height at upper ends thereof.

19. An apparatus for processing a substrate, the apparatus comprising:
a first body;
a second body combined with the first body to provide a treatment space for processing the substrate therein, and disposed below the first body;
a fluid supply unit for supplying a supercritical fluid to the treatment space;
a lifting unit for raising and lowering the first body or the second body so that a relative position of the first body and the second body changes between an open position where the treatment space is open to the outside and a closed position where the treatment space is closed off from the outside;
a substrate loader which is installed in the first body and in which a substrate loaded or unloaded by an external transfer robot at the open position is placed; and
a substrate supporter installed on the second body and supporting the substrate at the closed position,
wherein the substrate supporter includes:
a support plate;
a first support pin and a plurality of second support pins which are installed on the support plate to protrude upward from an upper surface of the support plate, and on which the substrate is placed, the plurality of second support pins having the same height, and
an upper end of the first support pin is provided higher than upper ends of the plurality of second support pins, and
the first support pin supports a center of the substrate,
the plurality of second support pins is arranged to surround the first support pin, and
a distance between each of the plurality of second support pins and the first support pin is the same, and intervals between the adjacent second support pins are provided to be same as each other.

20. The apparatus of claim 19, wherein the substrate loader includes:
a plurality of fixed rods fixedly coupled to the first body;
a support rod extending from the fixed rod toward an inside thereof and connecting the adjacent fixed rods among the plurality of fixed rods; and
a support protrusion formed on an upper surface of the support rod so as to protrude upward from the upper surface of the support rod, and
when viewed from above, the support protrusion is located outside the second support pin,
at the open position, an upper end of the support protrusion is located higher than upper ends of the first support pin and each of the second support pin, and
at the closed position, upper ends of the first support pin and each of the second support pin are located higher than the support protrusion.
